(19) United States
(12) Patent Application Publication
(10) Pub. No.: US 2025/0063949 A1
(43) Pub. Date: Feb. 20, 2025

(54) THERMOELECTRIC CONVERSION APPARATUS, ELECTRONIC DEVICE, AND WASTE HEAT RECYCLING SYSTEM

(71) Applicant: Canaan Creative Co., LTD., Beijing (CN)

(72) Inventors: Yuanyuan LI, Beijing (CN); Guangchang WANG, Beijing (CN); Nangeng ZHANG, Beijing (CN)

(21) Appl. No.: 18/938,935

(22) Filed: Nov. 6, 2024

Related U.S. Application Data
(63) Continuation of application No. PCT/CN2022/091941, filed on May 10, 2022.

(30) Foreign Application Priority Data
May 7, 2022 (CN) 202210493596.8
May 7, 2022 (CN) 202210495241.2
May 7, 2022 (CN) 202221088120.8
May 7, 2022 (CN) 202221090353.1

(51) Int. Cl. H10N 10/82; H10N 10/13; H10N 10/17; H10N 10/852

(52) U.S. Cl. CPC H10N 10/82; H10N 10/13; H10N 10/17; H10N 10/852

(57) ABSTRACT

The present application provides a thermoelectric conversion apparatus, an electronic device, and a waste heat recycling system. The thermoelectric conversion apparatus includes: a power generator including a first end face and a second end face opposite to each other; lead terminals, both the first end face and the second end face of the power generator being provided with the lead terminals, wherein in a case where there is a temperature difference between the second end face and the first end face of the power generator, electric potential is generated in the power generator, and electric energy is output through the lead terminals disposed on the second end face and the first end face of the power generator; and a supporter configured to support and fix the power generator.

### CROSS REFERENCE TO RELATED APPLICATIONS

The present application is a continuation application of International Application No. PCT/CN2022/091941, filed on May 10, 2022, which claims priority to and benefits of the Chinese Patent Application No. CN202210495241.2 filed on May 7, 2022, Chinese Patent Application No. CN202221088120.8 filed on May 7, 2022, Chinese Patent Application No. CN202210493596.8 filed on May 7, 2022, and Chinese Patent Application No. CN202221090353.1 filed on May 7, 2022. The entire contents of all of the above-identified applications are incorporated herein by reference.

### TECHNICAL FIELD

The present application relates to the field of energy technology, and in particular, to a thermoelectric conversion apparatus, an electronic device, and a waste heat recycling system.

### BACKGROUND

A large number of large-scale integrated circuits are disposed in an electronic device, and release a large amount of waste heat while consuming a large amount of electric energy during operation, such that energy consumption is increased, and an energy efficiency ratio of the electronic device is reduced. If the waste heat can be fully utilized, the energy efficiency ratio of the electronic device can be improved. Therefore, how to recycle the waste heat generated during the operation of the electronic device becomes an urgent technical problem to be solved.

### SUMMARY

The present application provides a thermoelectric conversion apparatus, an electronic device, and a waste heat recycling system.

In a first aspect, the present application provides a thermoelectric conversion apparatus, including: a power generator including a first end face and a second end face opposite to each other; lead terminals, both the first end face and the second end face of the power generator being provided with the lead terminals; in a case where there is a temperature difference between the first end face and the second end face of the power generator, the power generator outputs electric energy through the lead terminals disposed on the first end face and the second end face of the power generator; and a supporter configured to support and fix the power generator.

The power generator is a hollow columnar structure.

The supporter includes a first hollow columnar structure, and the power generator is located on a surface of the first hollow columnar structure.

The supporter includes a first hollow columnar structure and a second hollow columnar structure, which are coaxially arranged and have different radii, and the power generator is located between the first hollow columnar structure and the second hollow columnar structure.

The supporter is provided with a plurality of through holes penetrating through the supporter along a wall thickness direction of the supporter.

In the thermoelectric conversion apparatus provided in the embodiments of the present application, a case plate is provided with a plurality of through holes penetrating through the case plate along a wall thickness direction of the case plate, so that the second end face of the power generator can be made to approach the ambient temperature outside a case to increase the temperature difference between the first end face and the second end face of the power generator, thereby improving power generation efficiency of the power generator.

The case plate is provided with an embedding hole penetrating through the case plate along the wall thickness direction of the case plate, and the power generator is embedded in the embedding hole.

In the thermoelectric conversion apparatus provided in embodiments of the present application, by embedding the power generator in the embedding hole, the power generator can be easily fixed, and meanwhile, the first end face and the second end face of the power generator are made to approach a temperature of an accommodating space and a temperature outside the case, respectively, thereby improving the power generation efficiency of the power generator.

The supporter is a case, and an accommodating space is formed in the case; and the power generator is disposed on a surface of the case.

In the thermoelectric conversion apparatus provided in the embodiments of the present application, heat generated by a computing board can be recovered with the power generator disposed in the accommodating space of the case, thereby improving an energy efficiency ratio of a super computing device and reducing energy waste and environmental pollution.

The case includes a plurality of side surfaces, and at least one of the plurality of side surfaces of the case is provided with the power generator.

In the thermoelectric conversion apparatus provided in the embodiments of the present application, by disposing the power generator on at least one of the plurality of side surfaces of the case, design flexibility of the power generator can be improved, and cost of the super computing device can be reduced.

The power generator is attached to an inner side surface or an outer side surface of the case.

In the thermoelectric conversion apparatus provided in the embodiments of the present application, by attaching the power generator to the inner side surface or the outer side surface of the case, the power generator is made close to the accommodating space, thereby improving heat recovery efficiency of the power generator.

The case is an integrated structure.

In the thermoelectric conversion apparatus provided in the embodiments of the present application, the integral structure of the case can simplify an assembly process and improve assembly efficiency of the super computing device, thereby reducing production cost of the super computing device.

In the thermoelectric conversion apparatus provided in the embodiments of the present application, the integral structure of the case can reduce installation difficulty of the power generator and the case and improve installation efficiency.

The first end face of the power generator is a hot end face, the second end face of the power generator is a cold end face, the first end face of the power generator is disposed facing the accommodating space, and the second end face of the power generator is disposed away from the accommodating space.

In the thermoelectric conversion apparatus provided in the embodiments of the present application, disposing the hot end face of the power generator facing the accommodating space and the cold end face of the power generator away from the accommodating space can facilitate the improvement in the power generation efficiency of the power generator.

The thermoelectric conversion apparatus further includes one or more of: a heat sink attached to a heater, and configured to discharge heat generated by the heater; a control board disposed on an outer side of the case, and configured to control the heater; or a power supply disposed on the outer side of the case.

The lead terminals disposed on the first end face and the second end face are electrically connected to a power-consuming device for providing electrical signals to the power-consuming device.

In the thermoelectric conversion apparatus provided in the embodiments of the present application, the lead terminals are electrically connected to the power-consuming device in the super computing device, and the power-consuming device in the super computing device directly utilizes the electric energy generated by the power generator, thereby improving the energy efficiency ratio of the super computing device.

The power generator is a hollow columnar integral structure.

The power generator includes a plurality of sub-power generators arranged at intervals along a circumferential direction of the supporter, and connected in parallel or in series through conductors.

In the thermoelectric conversion apparatus provided in the embodiments of the present application, the power generator is arranged in the form of the plurality of sub-power generators, and the plurality of sub-power generators are arranged on the case at intervals or side by side, so that the sub-power generators can be arranged flexibly according to a size of the case, the space of the case can be effectively utilized, and the heat recovery efficiency of the power generator can be improved.

A material of the power generator is a semiconductor material including bismuth telluride; and a material of the lead terminals is a conductive metal.

In the thermoelectric conversion apparatus provided in the embodiments of the present application, bismuth telluride is used as a power generation material, and the power generation efficiency and operation stability of the super computing device can be improved due to good electrical conductivity of bismuth telluride.

Plating layers are disposed on surfaces of the power generator and the lead terminals, and a material of the plating layers is nickel or tin.

In the thermoelectric conversion apparatus provided in the embodiments of the present application, electrical connection performance of the power generator and the lead terminals can be improved due to good electrical conductivity of nickel or tin.

A package layer is disposed on an outer surface of the power generator and covers the power generator, one end of a lead terminal is disposed on an outer side of the package layer, and a material of the package layer is ceramic.

In the thermoelectric conversion apparatus provided in the embodiments of the present application, using ceramic as the material of the package layer has the advantages of low material cost, mature process, and excellent performance.

The thermoelectric conversion apparatus further includes an energy storage module, two input terminals of the energy storage module are electrically connected to the lead terminals disposed on the second end face and the first end face respectively, and the energy storage module is configured to store the electric energy output from the power generator.

In the thermoelectric conversion apparatus provided in the embodiments of the present application, by storing the electric energy with the energy storage module, flexibility of usage of the electric energy can be improved.

The thermoelectric conversion apparatus further includes a voltage stabilizer, two input terminals of the voltage stabilizer are electrically connected to the lead terminals disposed on the first end face and the second end face respectively, and two output terminals of the voltage stabilizer are electrically connected to the two input terminals of the energy storage module correspondingly.

In the thermoelectric conversion apparatus provided in the embodiments of the present application, the voltage stabilizer can improve stability of quantity of the electric energy input to the energy storage module and prolong service life of the energy storage module.

The thermoelectric conversion apparatus further includes a transformer, the two input terminals of the voltage stabilizer are electrically connected to the lead terminals disposed on the first end face and the second end face respectively, the two output terminals of the voltage stabilizer are electrically connected to two input terminals of the transformer respectively, and two output terminals of the transformer are electrically connected to the two input terminals of the energy storage module correspondingly.

In the thermoelectric conversion apparatus provided in the embodiments of the present application, the transformer disposed between the voltage stabilizer and the energy storage module can improve charge efficiency, so that the electric energy generated by the power generator can be stored on time.

The supporter includes a housing of a fan.

In the thermoelectric conversion apparatus provided in the embodiments of the present application, heat dissipation efficiency of the super computing device can be increased with the heat sink and the fan, so that a temperature of the accommodating space can be prevented from being too high and affecting performance of the super computing device.

The thermoelectric conversion apparatus further includes a medium driving module, the medium driving module includes a rotating shaft, blades, and a driving device, the rotating shaft is arranged along a direction of a central axis of the supporter, the blades are fixed at one end of the rotating shaft, an output terminal of the driving device is connected to the other end of the rotating shaft, the rotating shaft transmits a driving force from the driving device to the blades, and the blades are configured to provide power for flowing of a heat transfer medium.

A side of the power generator close to the blades is the first end face, and a side of the power generator away from the blades is the second end face.

In a second aspect, the present application provides an electronic device, including an electronic component and a thermoelectric conversion apparatus configured to recycle heat generated by the electronic component, and the thermoelectric conversion apparatus includes the thermoelectric conversion apparatus provided in the embodiments of the present application.

The lead terminals of the thermoelectric conversion apparatus are configured to provide electrical signals to a component in the electronic component.

The electronic component is a super computing device.

In a third aspect, the present application provides a waste heat recycling system, including: an electronic component, a thermoelectric conversion apparatus, and a power-consuming device, and lead terminals of the thermoelectric conversion apparatus are electrically connected to the power-consuming device for providing electrical signals for the power-consuming device.

According to the embodiments of the present application, the power generator is fixed to the supporter, and the second end face and the first end face of the power generator are both provided with the lead terminals; in the case where there is the temperature difference between the second end face and the first end face, electric potential is generated in the power generator, and electric energy is output through the lead terminals disposed on the second end face and the first end face of the power generator, so that waste heat is converted into the electric energy, thereby reducing energy consumption and pollution. A medium with a relatively high temperature is made to flow on an inner side of the supporter, so that a temperature difference between the inner side and an outer side of the supporter can be increased, thereby improving utilization efficiency of the waste heat and energy efficiency ratio of the electronic device.

It should be understood that what is described herein is not intended to indicate key features or critical features of the embodiments of the present application, and is not used to limit the scope of the present application. Other features of the present application will become apparent from the following description.

### BRIEF DESCRIPTION OF DRAWINGS

The accompany drawings are intended to provide a further understanding of the present application and constitute a part of the specification. Together with the embodiments of the present application, the drawings are used to explain the present application, but do not constitute any limitation to the present application. The above and other features and advantages will become more apparent to those of ordinary skill in the art through the description of specific exemplary embodiments with reference to the drawings.

FIG. 1 is a schematic structural diagram of a super computing device according to an embodiment of the present application;

FIG. 2 is a side view of a power generator according to an embodiment of the present application;

FIG. 3 is a schematic structural diagram of a case and a power generator according to an embodiment of the present application;

FIG. 4 is another schematic structural diagram of a case and a power generator according to an embodiment of the present application;

FIG. 5 is still another schematic structural diagram of a case and a power generator according to an embodiment of the present application;

FIG. 6 is still another schematic structural diagram of a case and a power generator according to an embodiment of the present application;

FIG. 7 is still another schematic structural diagram of a case and a power generator according to an embodiment of the present application;

FIG. 8 is a schematic diagram illustrating parallel connection of part of sub-power generators of a power generator according to an embodiment of the present application;

FIG. 9 is a schematic diagram illustrating series connection of part of sub-power generators of a power generator according to an embodiment of the present application;

FIG. 10 is another schematic structural diagram of a power generator according to an embodiment of the present application;

FIG. 11 is another schematic structural diagram of a super computing device according to an embodiment of the present application;

FIG. 12 is still another schematic structural diagram of a super computing device according to an embodiment of the present application;

FIG. 13 is still another schematic structural diagram of a super computing device according to an embodiment of the present application;

FIG. 14 is a schematic structural diagram of a super computing device according to an embodiment of the present application;

FIG. 15 is a side view of a power generator according to an embodiment of the present application;

FIG. 16 is a schematic structural diagram of a case and a power generator according to an embodiment of the present application;

FIG. 17 is another schematic structural diagram of a case and a power generator according to an embodiment of the present application;

FIG. 18 is still another schematic structural diagram of a case and a power generator according to an embodiment of the present application;

FIG. 19 is still another schematic structural diagram of a case and a power generator according to an embodiment of the present application;

FIG. 20 is still another schematic structural diagram of a case and a power generator according to an embodiment of the present application;

FIG. 21 is another schematic structural diagram of a super computing device according to an embodiment of the present application;

FIG. 22 is still another schematic structural diagram of a super computing device according to an embodiment of the present application;

FIG. 23 is still another schematic structural diagram of a super computing device according to an embodiment of the present application;

FIG. 24 is a schematic structural diagram of a super computing device according to an embodiment of the present application; and

FIG. 25 is a schematic structural diagram of a super computing device according to an embodiment of the present application.

In the drawings: 1—case; 10—electronic device; 11—computing board; 12—network interface card; 14—medium driving module; 15—accommodating space, 16—case frame, 17—case plate, 171—blind hole; 172—through hole; 173—embedding hole; 5—energy storage module; 6—heat sink; 7—control board; 8—fan; 9—power supply; 21—power generator; 31—first end face; 32—second end face; 33—sub-power generator; 33a, 33b, 33c—sub-power generators; 214—gap; 4—lead terminal; 41—first lead terminal; 42—second lead terminal; 23—supporter; 23a—first hollow columnar structure; 23b—second hollow columnar structure; 231—supporter outer wall; 232—supporter inner wall; 233—accommodating space; 234—through hole; 235—supporter body; 236—embedding space; 33—package layer; 26—medium driving module; 261—rotating shaft; 262—blade; 27—housing; 81—air inlet fan; 43—air outlet fan; 44—thermoelectric conversion apparatus; 46—lighting device; 47—voltage stabilizer; 48—transformer.

### DETAIL DESCRIPTION OF EMBODIMENTS

In order to enable those of ordinary skill in the art to better understand the technical solutions of the present application, exemplary embodiments of the present application are described below with reference to the drawings. For facilitating the understanding, various details of the embodiments of the present application are described when describing the exemplary embodiments and should be regarded as being merely exemplary. Accordingly, those of ordinary skill in the art should be aware that various changes and modifications to the embodiments described herein may be made without departing from the scope and spirit of the present application. Moreover, descriptions of well-known functions and structures are omitted from the following description for clarity and conciseness.

All the embodiments of the present application and features therein can be combined with each other if no conflict is incurred.

As used herein, the term “and/or” includes any one or all combinations of one or more associated listed items.

The terms used herein are only used to describe particular embodiments, and are not intended to limit the present application. As used herein, “a” and “the” indicating a singular form is also intended to indicate a plural form. Unless expressly stated otherwise, it should be further understood that the term “include” and/or “made of . . . ” used herein indicates the presence of the described features, integers, steps, operations, elements and/or components, but does not exclude the presence or addition of one or more other features, integers, steps, operations, elements, components and/or combinations thereof. The terms “connect”, “couple” and the like are not restricted to physical or mechanical connection, but may also indicate electrical connection, whether direct or indirect.

Unless otherwise defined, all terms (including technical and scientific terms) used herein have the same meaning as commonly understood by those of ordinary skill in the art. It should be further understood that terms, such as those defined in commonly used dictionaries, should be interpreted as having a meaning that is consistent with a meaning in the context of the related art and the present application, and should not be interpreted in an idealized or overly formal sense unless expressly so defined herein.

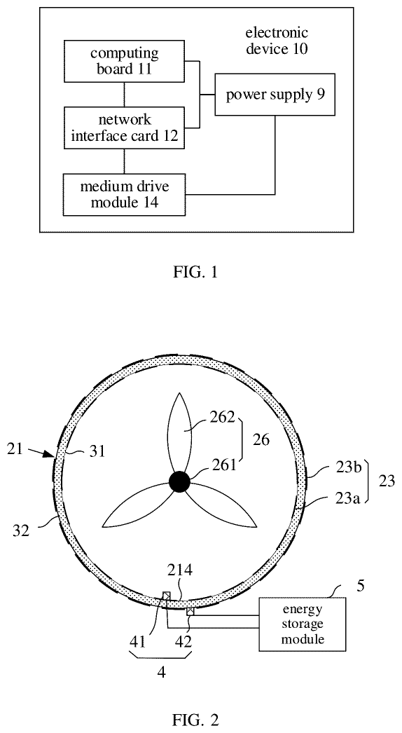

FIG. 1 is a schematic structural diagram of an electronic device adopted in an embodiment of the present application. As shown in FIG. 1, the electronic device 10 includes a computing board 11, a network interface card 12, a power supply 9, and a medium driving module 14. An output terminal of the power supply 9 is electrically connected to the computing board 11, the network interface card 12, and the medium driving module 14 respectively, and is configured to provide electric energy for the computing board 11, the network interface card 12, and the medium driving module 14 to operate normally. The computing board 11 is configured to run a specific algorithm to compute data to be processed, the network interface card 12 is configured to perform network connection with other external electronic devices, and the computing board 11 is in signal connection with the network interface card 12, and may acquire the data to be processed through the network interface card 12 and transmit a processing result to the other electronic devices through the network interface card 12. The medium driving module 14 is configured to discharge the heat generated during the operation of the computing board 11, the network interface card 12, and the power supply 9, so as to allow the electronic device to operate in a desired temperature range.

The computing board 11 is a mainboard of the electronic device 10, and includes a substrate, a chip, a heat sink, and other electronic components. The computing power of the computing board 11 is an index for measuring computing power and computing performance of the electronic device 10, and may be represented by the number of operations of a hash algorithm per second. The chip may be a Central Processing Unit (CPU), a Graphics Processing Unit (GPU), or an Application Specific Integrated Circuit (ASIC) chip.

The electronic components such as the computing board 11, the network interface card 12, and the power supply 9 in the electronic device consume a large amount of electric energy and generate a large amount of waste heat during operation, such that an energy efficiency ratio of the electronic device is low, and cause energy waste and environment pollution.

The present application provides a thermoelectric conversion apparatus, which can recycle the waste heat generated by the electronic device, so as to improve the energy efficiency ratio of the electronic device and reduce energy waste and environmental pollution.

FIG. 2 is a schematic structural diagram of a thermoelectric conversion apparatus according to an embodiment of the present application. As shown in FIG. 2, the thermoelectric conversion apparatus includes a power generator 21, lead terminals 4, and a supporter 23. The supporter 23 is configured to support and fix the power generator 21, and the lead terminals 4 are electrically connected to the power generator 21.

In some embodiments, the power generator 21 includes a first end face 31 and a second end face 32 opposite to each other. In a case where there is a temperature difference between the first end face 31 and the second end face 32 of the power generator 21, electric potential is generated in the power generator 21, that is, electric energy is generated.

In some embodiments, the power generator 21 is a hollow columnar structure, and a heater may be disposed in the power generator 21 having the hollow columnar structure, so that the power generator 21 is disposed around the heater, which can increase a recycling rate of the waste heat.

In the present embodiment, the first end face 31 may be a hot end face, and the second end face 32 may be a cold end face; alternatively, the first end face 31 may be a cold end face, and the second end face 32 may be a hot end face.

In some embodiments, a lead terminal 4 is disposed on each of the first end face 31 and the second end face 32 of the power generator 21, and is configured to output the electric energy generated in the power generator 21.

Illustratively, the lead terminals 4 include a first lead terminal 41 and a second lead terminal 42. The first lead terminal 41 is disposed on the first end face 31 of the power generator 21, and the second lead terminal 42 is disposed on the second end face 32 of the power generator 21. When the electric potential is generated in the power generator 21, the electric energy may be output through the first lead terminal 41 and the second lead terminal 42. The electric energy may be recycled when the first lead terminal 41 and the second lead terminal 42 are connected to a power-consuming device, and may be stored when the first lead terminal 41 and the second lead terminal 42 are connected to an energy storage module.

In some embodiments, the supporter 23 is a hollow columnar structure.

In some embodiments, the supporter 23 includes a first hollow columnar structure 23a and a second hollow columnar structure 23b, which are coaxially arranged and have different radii, and an accommodating cavity is formed between the first hollow columnar structure 23a and the second hollow columnar structure 23b. The power generator 21 is located in the accommodating cavity between the first hollow columnar structure and the second hollow columnar structure, that is, the first hollow columnar structure 23a, the power generator 21, and the second hollow columnar structure 23b are sequentially nested from inside to outside.

In some embodiments, the supporter 23 includes a first hollow columnar structure, and the power generator 21 is disposed on a surface of the first hollow columnar structure. In the embodiments of the present application, the power generator 21 may be disposed on an inner surface of the supporter 23 or an outer surface of the supporter 23.

In some embodiments, the supporter 23 is provided with a plurality of through holes penetrating through the supporter 23 along a wall thickness direction of the supporter 23. The through holes may facilitate an increase in a temperature difference between the first end face 31 and the second end face 32 of the power generator 21, thereby improving heat recovery efficiency.

For example, the supporter 23 is a hollow cylindrical structure. A shape of a projection of the supporter 23 on a cross section perpendicular to an axis may be a square ring, a diamond ring or other shaped rings, and is not limited in the present application. A medium may flow on an inner side and an outer side of the supporter 23 along an axial direction of the supporter 23, and may be the air or a liquid which may be a coolant.

It should be noted that the supporter 23 having the hollow columnar structure in the present embodiment can divide the space into an inner space and an outer space, i.e., a closed or semi-closed space and an open space. The inner side of the supporter 23 refers to a side of the supporter 23 in the closed or semi-closed space, and the outer side of the supporter 23 refers to a side of the supporter 23 in the open space.

Media having different temperatures flow on the inner side and the outer side of the supporter 23 respectively. For example, a medium having a higher temperature flows on the inner side of the supporter 23, and a medium having a lower temperature flows on the outer side of the supporter 23. Alternatively, the medium having the lower temperature flows on the inner side of the supporter 23, and the medium having the higher temperature flows on the outer side of the supporter 23. It should be noted that the media flowing on the inner side and the outer side of the supporter 23 may be of two types or the same type, which is not limited in the present application. For example, the medium flowing on the inner side of the supporter 23 is the air, and the medium flowing on the outer side of the supporter 23 is water.

In some embodiments, the power generator 21 is a hollow columnar integral structure. For example, the power generator 21 is a hollow cylindrical structure, and the two lead terminals 4 are disposed on the first end face 31 (an inner wall of the power generator 21) and the second end face 32 (an outer wall of the power generator 21) of the hollow cylindrical power generator 21, respectively. The power generator 21 having the integral structure is easy to assemble, which simplifies assembly difficulty of the thermoelectric conversion apparatus, and improves assembly efficiency.

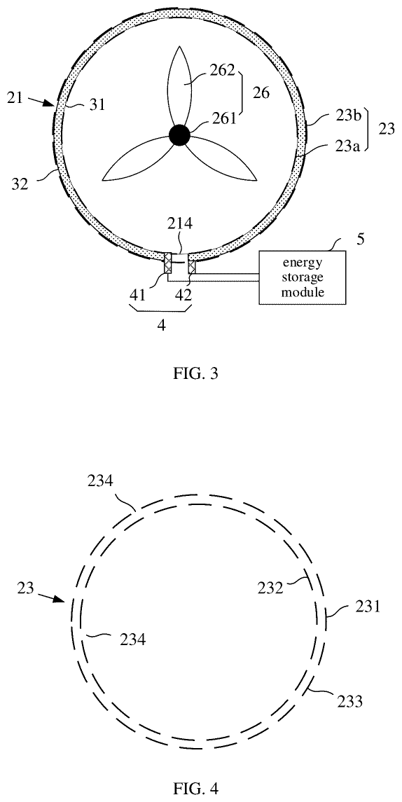

In some embodiments, as shown in FIG. 3, in order to facilitate machining the power generator 21 and connecting the lead terminals 4 to lead wires, a gap 214 is provided at the power generator 21 in a circumferential direction of the power generator 21, that is, the power generator 21 is not a closed hollow columnar structure. Illustratively, in a case where a shape of the power generator 21 is a hollow cylinder, a shape of a projection of the power generator 21 on a cross section perpendicular to an axis is a C shape due to the gap 214. The two lead terminals 4 are both disposed at the gap 214, and are disposed on an inner wall and an outer wall of the power generator 21 respectively. A lead wire connected to the lead terminal 4 disposed on the inner wall may extend to an outer side of the power generator 21 through the gap 214.

As shown in FIG. 2 and FIG. 4, the supporter 23 includes a supporter outer wall 231 and a supporter inner wall 232, an accommodating space 15 is formed between the supporter outer wall 231 and the supporter inner wall 232, and the power generator 21 is embedded in the accommodating space 15 of the supporter 23. Since the supporter outer wall 231 and the supporter inner wall 232 isolate the power generator 21 from the media, there are temperature differences between the first end face 31 of the power generator 21 and a medium and between the second end face 32 of the power generator 21 and the other medium, which affects power generation efficiency of the power generator 21. For this reason, a plurality of through holes 234 are provided on the supporter outer wall 231 and the supporter inner wall 232. With the through holes 234, a temperature of the first end face 31 of the power generator 21 and a temperature of the second end face 32 of the power generator 21 can be made consistent with a medium temperature of the inner side of the supporter 23 and a medium temperature of the outer side of the supporter 23 as much as possible, respectively.

In some embodiments, the power generator 21 includes a plurality of sub-power generators 33, which are arranged at intervals along a circumferential direction of the supporter 23, and are connected in parallel or in series through lead wires. When the plurality of sub-power generators 33 are electrically connected in parallel, a current value output by the power generator can be increased. When the plurality of sub-power generators 33 are electrically connected in series, a voltage value output by the power generator can be increased.

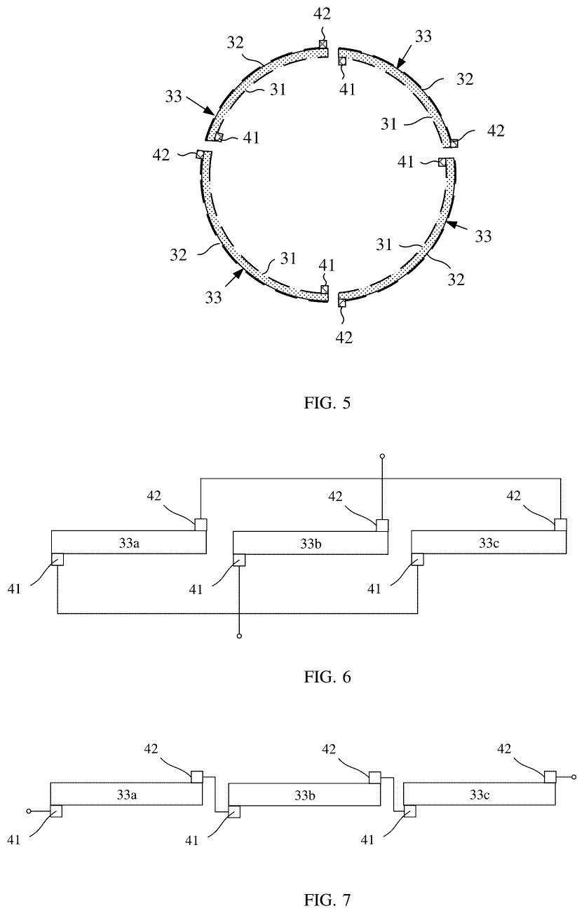

As shown in FIG. 5, the power generator 21 includes four sub-power generators 33 each including a first end face 31 and a second end face 32 opposite to each other. A first lead terminal 41 is disposed on the first end face 31, and a second lead terminal 42 is disposed on the second end face 32. In a case where there is a temperature difference between the first end face 31 and the second end face 32 of the sub-power generator 33, electric energy may be generated in the sub-power generator 33, and may be output through the lead wires connected to the first lead terminal 41 and the second lead terminal 42.

FIG. 6 is a schematic diagram illustrating parallel connection of part of sub-power generators of a power generator. As shown in FIG. 6, the power generator 21 includes three sub-power generators 33a, 33b, 33c, the first lead terminal 41 of the sub-power generator 33a, the first lead terminal 41 of the sub-power generator 33b, and the first lead terminal 41 of the sub-power generator 33c are electrically connected, and the second lead terminal 42 of the sub-power generator 33a, the second lead terminal 42 of the sub-power generator 33b, and the second lead terminal 42 of the sub-power generator 33c are electrically connected, thereby connecting the three sub-power generators 33a, 33b, 33c in parallel and outputting the electric energy generated by the three sub-power generators 33a, 33b, 33c.

FIG. 7 is a schematic diagram illustrating series connection of part of sub-power generators of a power generator. As shown in FIG. 7, the power generator 21 includes three sub-power generators 33a, 33b, 33c, the second lead terminal 42 of the sub-power generator 33a is electrically connected to the first lead terminal 41 of the sub-power generator 33b, and the second lead terminal 42 of the sub-power generator 33b is electrically connected to the first lead terminal 41 of the sub-power generator 33c, thereby outputting the electric energy generated by the three sub-power generators 33a, 33b, 33c through the first lead terminal 41 of the sub-power generator 33a and the second lead terminal 42 of the sub-power generator 33c.

It should be noted that the case where the power generator 21 includes only three sub-power generators 33 as illustrated by FIG. 6 and FIG. 7 is not intended to limit the number of the sub-power generators 33.

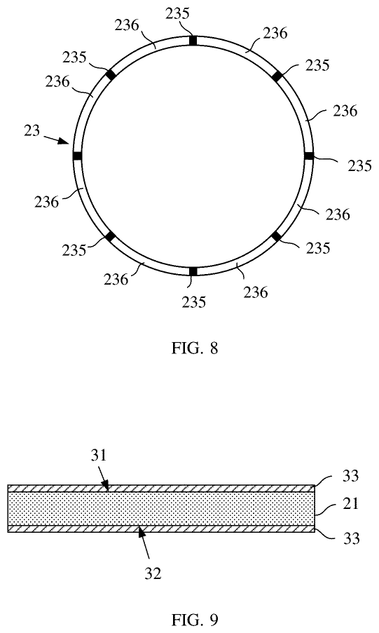

As shown in FIG. 8, the supporter 23 includes a supporter body 235 and a plurality of embedding spaces 236 provided at intervals in a circumferential direction of the supporter body 235. The embedding spaces 236 correspond to the sub-power generators 33 in number, and each sub-power generator is correspondingly embedded in one embedding space 236. During assembly, the sub-power generators can be fixed to the supporter 23 quickly by using the embedding spaces 236, thereby improving the assembly efficiency.

In some embodiments, a material of the power generator 21 is a semiconductor material. Illustratively, the semiconductor material includes bismuth telluride or other semiconductor materials. Bismuth telluride has good electrical conductivity but poor thermal conductivity, and can improve power generation efficiency and operation stability of the thermoelectric conversion apparatus when used in the thermoelectric conversion apparatus.

In some embodiments, a material of the lead terminals is a conductive metal such as copper. Copper has good electrical conductivity and is low in cost. In some embodiments, Teflon lead wires or other high temperature-resistant lead wires may be used as the lead wires connected to the lead terminals 4.

In some embodiments, plating layers (not shown) are disposed on surfaces of the power generator 21 and the lead terminals. In a case where the material of the power generator 21 is not favorable for welding, for example, it is not easy for coating a solder, the plating layer can improve weldability of the power generator 21.

In some embodiments, a material of the plating layers is nickel or tin. In a case where the material of the power generator 21 is bismuth telluride and the solder is a tin-bismuth alloy, bismuth telluride may be melted into the solder, and copper impurities may easily diffuse into bismuth telluride at a relatively low temperature, which worsens thermoelectric property of bismuth telluride. The plating layers made of nickel or tin may serve as barriers to prevent the copper impurities from diffusing into bismuth telluride, thereby avoiding deterioration of the thermoelectric property of bismuth telluride. Disposing the plating layers made of nickel or tin on the surfaces of the lead terminals 4 can also facilitate the improvement in welding performance of the lead terminals 4. In some embodiments, a thickness of the plating layers is in a range of 0.1 mm to 0.3 mm.

FIG. 9 is a schematic diagram of a partial structure of a thermoelectric conversion apparatus according to an embodiment of the present application. As shown in FIG. 9, a package layer 33 is disposed on an outer surface of the power generator 21 and covers the power generator 21. One end of the lead terminal 4 is disposed on an outer side of the package layer 33, that is, one end of the lead terminal 4 is exposed from the package layer 33 for facilitating electrical connection.

In some embodiments, a material of the package layer 33 is ceramic or other suitable materials. Using ceramic as the material of the package layer 33 has the advantages of low material cost, mature process, and excellent performance.

As shown in FIG. 2, the thermoelectric conversion apparatus further includes an energy storage module 5, and two input terminals of the energy storage module 5 are electrically connected to the lead terminals 4 disposed on the second end face 32 and the first end face 31 of the power generator 21 respectively, so as to obtain and store the electric energy generated by the power generator 21. The energy storage module 5 may be a storage battery, or other modules capable of storing electric energy, and the form of the energy storage module 5 is not limited in the present application. The energy storage module 5 may be further connected to other power-consuming devices for supplying electric energy to the other power-consuming devices.

In some embodiments, the thermoelectric conversion apparatus further includes a voltage stabilizer 47, two input terminals of the voltage stabilizer 47 are electrically connected to the lead terminals 4 disposed on the first end face 31 and the second end face 32 respectively, and two output terminals of the voltage stabilizer 47 are electrically connected to the two input terminals of the energy storage module 5 correspondingly, that is, the voltage stabilizer 47 is disposed between output terminals of the power generator 21 and the energy storage module 5, that is, electric energy generated by the power generator 21 is stored the in the energy storage module 5 through the voltage stabilizer 47.

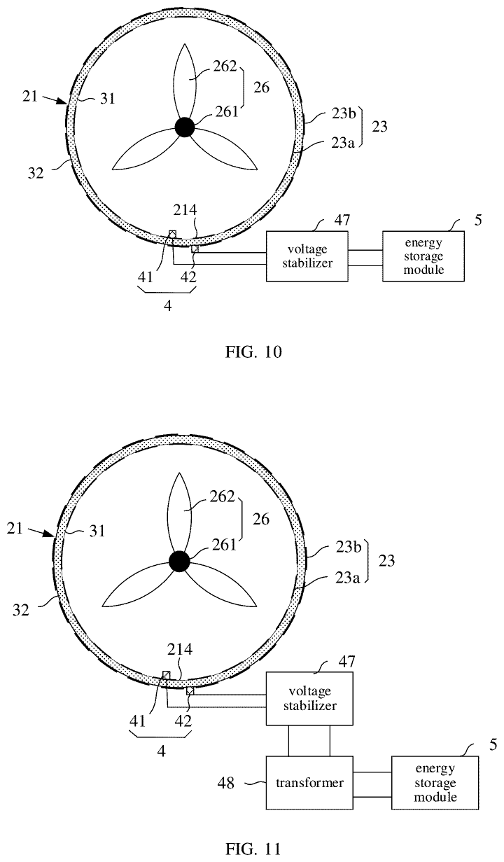

As shown in FIG. 10, the first end face 31 of the power generator 21 is electrically connected to the first input terminal of the voltage stabilizer 47 through the first lead terminal 41, the second end face 32 of the power generator 21 is electrically connected to the second input terminal of the voltage stabilizer 47 through the second lead terminal 42, the first output terminal of the voltage stabilizer 47 is electrically connected to the first input terminal of the energy storage module 5, and the second output terminal of the voltage stabilizer 47 is electrically connected to the second input terminal of the energy storage module 5.

In some embodiments, the thermoelectric conversion apparatus further includes a transformer 48, the two input terminals of the voltage stabilizer 47 are electrically connected to the lead terminals 4 disposed on the first end face 31 and the second end face 32 respectively, the two output terminals of the voltage stabilizer 47 are electrically connected to two input terminals of the transformer 48 respectively, and two output terminals of the transformer 48 are electrically connected to the two input terminals of the energy storage module 5 respectively, that is, the voltage stabilizer 47 and the transformer 48 are sequentially disposed between the output terminals of the power generator 21 and the energy storage module 5, and the electric energy is stored in the energy storage module 5 through the voltage stabilizer 47 and the transformer 48.

As shown in FIG. 11, the first end face 31 of the power generator 21 is electrically connected to the first input terminal of the voltage stabilizer 47 through the first lead terminal 41, the second end face 32 of the power generator 21 is electrically connected to the second input terminal of the voltage stabilizer 47 through the second lead terminal 42, the first output terminal of the voltage stabilizer 47 is electrically connected to the first input terminal of the transformer 48, and the second output terminal of the voltage stabilizer 47 is electrically connected to the second input terminal of the transformer 48. The first output terminal of the transformer 48 is electrically connected to the first input terminal of the energy storage module 5, and the second output terminal of the transformer 48 is electrically connected to the second input terminal of the energy storage module 5.

In some embodiments, as shown in FIG. 4, FIG. 10, and FIG. 11, the thermoelectric conversion apparatus further includes a medium driving module 26 configured to drive a medium to flow. The medium may be the air, or other gases or liquids capable of carrying heat. In some embodiments, the medium driving module 26 includes a rotating shaft 261, blades 262, and a driving device (not shown). The rotating shaft 261 is arranged along a direction of a central axis of the supporter 23, for example, the rotating shaft 261 coincides with or is parallel to the central axis of the supporter 23. The central axis of the supporter 23 is a center of symmetry of the hollow columnar supporter 23. The blades 262 are fixed at one end of the rotating shaft 261, an output terminal of the driving device is connected to the other end of the rotating shaft 261, the rotating shaft 261 transmits a driving force from the driving device to the blades 262, and the blades 262 are rotated to provide power for the flowing of a heat medium and a cold medium. The number of the blades 262 may be 2, 3 or more, and is not limited in the present application. A plurality of blades 262 are uniformly distributed along a circumferential direction of the rotating shaft 261, so as to provide the medium with uniform power.

In some embodiments, the medium driving module 26 may be blades, the thermoelectric conversion apparatus serves as a housing of a fan or a part of the housing, and the supporter 23 may be the housing of the fan.

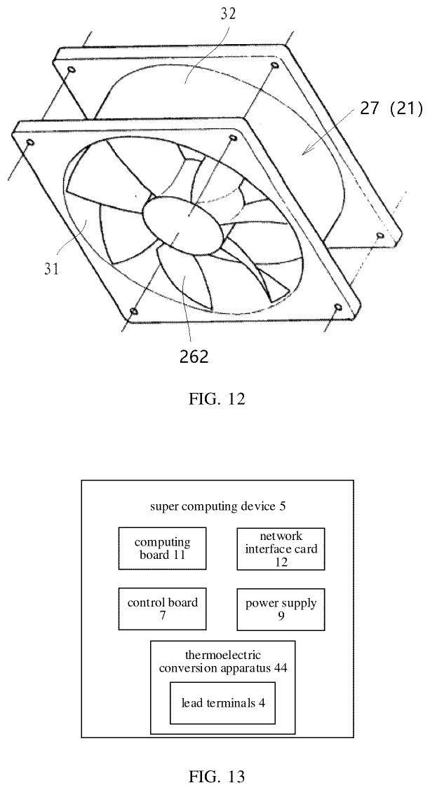

FIG. 12 is a schematic structural diagram of a thermoelectric conversion apparatus being disposed in a fan according to the present application. As shown in FIG. 2 and FIG. 12, the fan includes a housing 27 and blades 262, the blades 262 are disposed on an inner side of the housing 27, the housing 27 adopts the structure of the thermoelectric conversion apparatus provided in the present application, the inner side of the housing 27 refers to the side where the first end face 31 of the power generator 21 is located, and an outer side of the housing 27 refers to the side where the second end face 32 of the power generator 21 is located.

With the blades, a gas with a relatively high temperature (the temperature of the gas is raised due to the heat from the electronic device) is gathered to flow on the inner side of the housing 27, which facilitates an increase in a temperature difference between the inner side and the outer side of the housing 27, i.e., an increase in the temperature difference between the first end face 31 and the second end face 32 of the power generator 21, so that the efficiency of converting the waste heat into the electric energy can be improved, and energy consumption and pollution can be reduced. Meanwhile, the energy efficiency ratio of the electronic device and a utilization rate of the electric energy can be increased.

In some embodiments, a side of the power generator 21 close to the blades 262 is the side where the first end face 31 is located, and a side of the power generator 21 away from the blades 262 is the side where the second end face 32 is located. In order to improve heat dissipation efficiency of a specific space, the medium driving module 26 drives the medium with the relatively high temperature to flow to make a temperature of the medium flowing inside the supporter 23 be higher than a temperature of the medium flowing outside the supporter 23. The first end face 31 of the power generator 21 is disposed on the side facing the blades 262, and the second end face 32 of the power generator 21 is disposed on the side away from the blades 262. The side of the power generator 21 close to the blades 262 is the side where the first end face 31 is located, the side of the power generator 21 away from the blades 262 is the side where the second end face 32 is located, and enabling the medium with the relatively high temperature to flow on the inner side of the supporter 23 can facilitate the increase in the temperature difference between the first end face 31 and the second end face 32 of the power generator 21, thereby improving recovery efficiency of the waste heat.

According to the embodiments of the present application, the power generator 21 is fixed to the supporter 23 having the hollow columnar structure, and the second end face 32 and the first end face 31 of the power generator 21 are both provided with the lead terminals 4. In the case where there is the temperature difference between the second end face 32 and the first end face 31, the electric potential is generated in the power generator 21, and the electric energy is output through the lead terminals 4 disposed on the second end face 32 and the first end face 31 of the power generator 21, so that the waste heat is converted into the electric energy, thereby reducing energy consumption and pollution. Meanwhile, the energy efficiency ratio of the electronic device is improved, and the utilization rate of the electric energy is improved.

An embodiment of the present application further provides an electronic device, which includes an electronic component and a thermoelectric conversion apparatus configured to recycle heat generated by the electronic component, and the thermoelectric conversion apparatus is the thermoelectric conversion apparatus provided in the embodiments of the present application.

In some embodiments, as shown in FIG. 13, the electronic device may be a super computing device 5, which includes at least one of a computing board 11, a control board 7, a network interface card 12, and a power supply 9. The computing board 11 is a mainboard of the electronic device, includes an ASIC chip, a CPU or a GPU, and provides computing power for the super computing device. The control board 7 is configured to control the computing board 11, the network interface card 12, and the power supply 9. The network interface card 12 is provided with standard network ports. The power supply 9 supplies electric energy to the super computing device to ensure normal operation of each electronic component in the super computing device. In some embodiments, the electronic components may further include a memory and a hard disk configured to store and install a mining program.

The lead terminals 4 of the thermoelectric conversion apparatus 44 are configured to provide electrical signals to a component in the electronic component, that is, the lead terminals 4 of the thermoelectric conversion apparatus 44 are configured to provide the electrical signals to the computing board 11, the control board 7, the network interface card 12, and the power supply 9 of the super computing device. Specifically, the thermoelectric conversion apparatus may simultaneously provide the electrical signals to the computing board 11, the control board 7, the network interface card 12, and the power supply 9 of the super computing device 5, or may provide the electrical signals to at least one component in the super computing device.

The thermoelectric conversion apparatus provided in the embodiments of the present application is described below by taking the super computing device as an example.

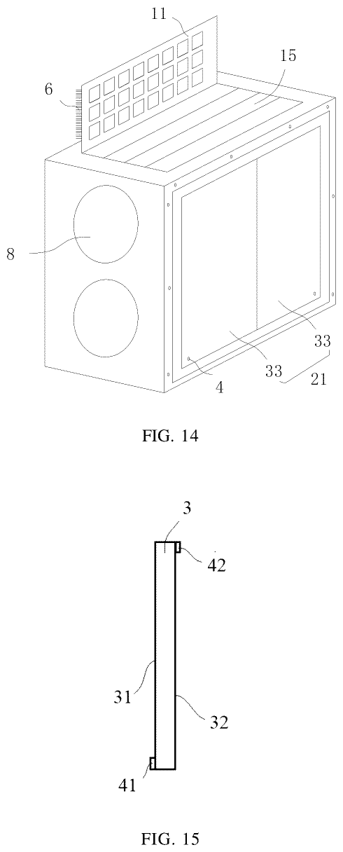

FIG. 14 is a schematic structural diagram of a super computing device according to an embodiment of the present application, and FIG. 15 is a side view of a power generator according to an embodiment of the present application. As shown in FIG. 14 and FIG. 15, the super computing device provided in the embodiments of the present application includes a case 1, the computing board 11, the power generator 21, and the lead terminals 4.

The case 1 is provided therein with an accommodating space 15, which is configured to accommodate key components of the super computing device. A shape of the accommodating space 15 may be a square or other shapes, and is not limited in the present application. A material of the case 1 may be metal or plastic.

The computing board 11 is disposed in the accommodating space 15, and generates heat during operation.

In some embodiments, the computing board 11 is the mainboard of the super computing device, and the computing power of the computing board 11 is an index for measuring computing power and computing performance of the super computing device. The computing power of the computing board 11 may be represented by the number of operations of a hash algorithm per second.

In some embodiments, the computing board 11 includes a chip, which may be a CPU, a GPU, or an ASIC chip.

The computing board 11 is configured to run a specific algorithm to compute data to be processed, a network interface card (not shown) is configured to perform network connection with other external electronic devices, and the computing board 11 is in signal connection with the network interface card, and may acquire the data to be processed through the network interface card and transmit a processing result to the other electronic devices through the network interface card.

According to the embodiments of the present application, the waste heat discharged by the computing board 11 during the operation thereof may cause a temperature of the accommodating space 15 to be higher than a temperature outside the accommodating space 15, and the temperature of the accommodating space 15 may be above 75° C. Therefore, the performance of the computing board 11 may be affected if the accommodating space 15 is not cooled.

The power generator 21 is disposed at the case 1, and includes a first end face 31 and a second end face 32 opposed to each other.

In some embodiments, the power generator 21 is disposed on a surface of the case 1, the first end face 31 of the power generator 21 faces the accommodating space 15, and the second end face 32 of the power generator 21 is away from the accommodating space 15, that is, the first end face 31 of the power generator 21 is disposed on a side close to the accommodating space 15, and the second end face 32 of the power generator 21 is disposed on a side away from the accommodating space 15. Since the temperature of the accommodating space 15 is higher and there is a temperature difference between an inner side of the case 1 and an outer side of the case 1, the power generator 21 is disposed on the surface of the case 1 to cause a temperature difference between the first end face 31 and the second end face 32 of the power generator 21, so as to enable the power generator 21 to generate electric energy therein.

In the embodiments of the present application, the first end face 31 and the second end face 32 are both provided with the lead terminals 4, and the electric energy generated by the power generator 21 is output through the lead terminals 4 in a case where there is the temperature difference between the first end face 31 and the second end face 32 of the power generator 21.

For example, as shown in FIG. 15, the first end face 31 is provided with the first lead terminal 41, and the second end face 32 is provided with the second lead terminal 42. In the case where there is the temperature difference between the first end face 31 and the second end face 32 of the power generator 21, the electric energy generated in the power generator 21 are output through the first lead terminal 41 and the second lead terminal 42.

In the embodiments of the present application, the first end face 31 may be a hot end face, and the second end face 32 may be a cold end face; alternatively, the first end face 31 may be a cold end face, and the second end face 32 may be a hot end face.

In the super computing device provided in the present application, the power generator disposed in the accommodating space of the case is used to recover the heat generated by the computing board, which can improve an energy efficiency ratio of the super computing device and reduce energy waste and environmental pollution.

In some embodiments, the case 1 includes a plurality of side surfaces, and the power generator 21 is disposed on at least one side surface of the case.

A case frame 16 is provided on a side surface of the case 1, and the power generator 21 is disposed on the case frame 16.

It should be noted that the number of the side surfaces of the case 1 is not limited in the embodiments of the present application as long as the accommodating space for accommodating the computing board 11 may be formed. A shape of the case 1 may be a hexahedron, an octahedron or other shapes, and is not limited in the embodiments of the present application.

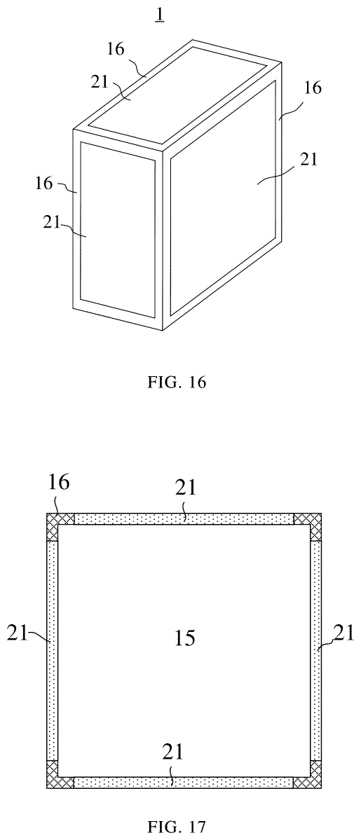

Illustratively, as shown in FIG. 16 and FIG. 17, the case 1 includes six side surfaces, which are a top side surface, a bottom side surface, a left side surface, a right side surface, a front side surface, and a rear side surface. The power generator 21 may be disposed on any one or more of the six side surfaces. For example, the power generator 21 is disposed on the top side surface, the left side surface, and the right side surface of the case 1, or the power generator 21 is disposed only on the left side surface and the right side surface of the case 1, or the power generator 21 is disposed on each of the six side surfaces of the case 1.

In the embodiments of the present application, by disposing the power generator 21 on the side surface of the case 1 to directly use the power generator 21 as a part of the case 1, cost of the super computing device can be saved.

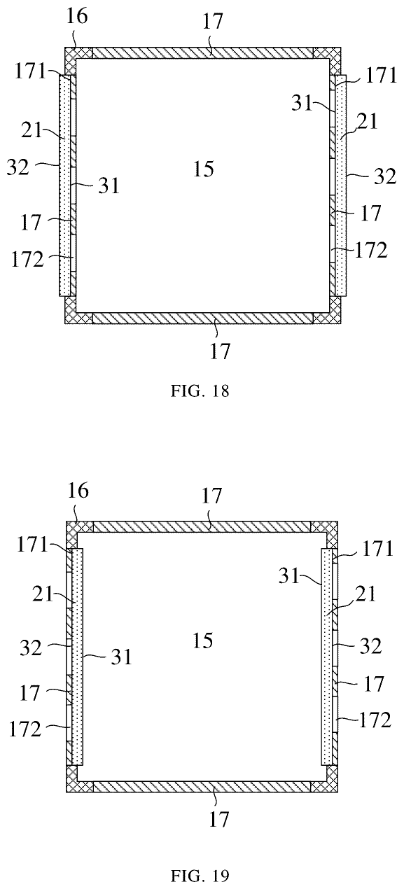

In some embodiments, as shown in FIG. 18, the case 1 includes a case frame 16 and a case plate 17, the case frame 16 includes a plurality of side surfaces, the case plate 17 is fixed to at least one side surface of the case frame 16, and at least one case plate 17 is provided with the power generator 21.

In the embodiments of the present application, the power generator 21 is not directly fixed to the case frame 16, but is fixed to the case frame 16 through the case plate 17, that is, the power generator 21 is fixed to the case plate 17, and the case plate 17 is then fixed to the case frame 16.

It should be noted that the case frame 16 includes the plurality of side surfaces, and each side surface may be provided with the case plate 17, or one or more side surfaces may be provided with the case plate 17. It should be further noted that the number of case plates 17 may be not the same as that of power generators 21, and the power generators 21 may be selectively disposed on the case plates 17. For example, the power generators 21 may be disposed on all the case plates 17, or may be provided on one or more case plates 17.

In some embodiments, when part of the side surfaces of the case frame 16 are provided with the case plates 17, the power generators 21 may be selectively disposed on the case plates 17, or may be directly disposed on the case frame 16.

In the super computing device provided in the embodiments of the present application, by disposing the power generator on any one side surface of the case 1, design flexibility of the power generator 21 can be increased, and the cost of the super computing device can be reduced.

In some embodiments, as shown in FIG. 18 and FIG. 19, the power generator 21 is attached to an inner side surface or an outer side surface of the case 1.

In some embodiments, the case plate 17 is disposed on a sidewall of the case 1, and the power generator 21 is disposed on the case plate 17. As shown in FIG. 18, in a case where the power generator 21 is attached to the outer side surface of the case plate 17, the first end face 31 of the power generator 21 is attached to the case plate 17, and the second end face 32 of the power generator 21 is adjacent to the environment. As shown in FIG. 19, in a case where the power generator 21 is attached to the inner side surface of the case plate 17, the first end face 31 of the power generator 21 is adjacent to the accommodating space 15, and the second end face 32 of the power generator 21 is attached to the case plate 17.

In the embodiments of the present application, the case plate 17 is provided with a blind hole 171, which may be disposed on an inner side or an outer side of the case plate 17. In a case where the blind hole 171 is disposed on the inner side of the case plate 17, the power generator 21 is correspondingly disposed on the inner side surface of the case plate 17. In a case where the blind hole 171 is provided on the outer side of the case plate 17, the power generator 21 is correspondingly disposed on the outer side surface of the case plate 17.

According to the embodiments of the present application, by attaching the power generator to the inner side surface or the outer side surface of the case, the power generator is made close to the accommodating space, which can improve heat recovery efficiency of the power generator.

According to the embodiments of the present application, by using the case plate 17 to bear the power generator 21, a size of the power generator 21 can be adjusted flexibly, without being limited by a size of the case frame 16.

In some embodiments, as shown in FIG. 18 and FIG. 19, the case plate 17 are provided with a plurality of through holes 172 penetrating through the case plate 17 along a wall thickness direction of the case plate 17, and positions of the plurality of through holes 172 correspond to the position of the power generator 21.

Arrangement and sizes of the plurality of through holes 172 are not limited in the embodiments of the present application. For example, the plurality of through holes 172 may be arranged in a rectangular array or a circular array.

According to the embodiments of the present application, a surface temperature of the power generator 21 is made close to the temperature of the accommodating space 15 or the ambient temperature with the through hole 172, so that the quantity of the electric energy generated by the power generator 21 is increased, and the recycling rate of the waste heat is increased. Illustratively, in the case where the power generator 21 is attached to the inner side surface of the case plate 17, the through holes 172 can help temperature of the second end face 32 of the power generator 21 approach the ambient temperature outside the case 1. In the case where the power generator 21 is attached to the outer side surface of the case plate 17, the through holes 172 can help temperature of the first end face 31 of the power generator 21 approach the temperature in the accommodating space 15.

In the embodiments of the present application, in addition to attaching the power generator 21 to the inner side surface or the outer side surface of the case plate 17, the power generator 21 may be embedded in the case plate 17, so as to maximize a contact area of the first end face 31 of the power generator 21 with the accommodating space 15 and a contact area of the second end face 32 of the power generator 21 with the environment outside the case 1.

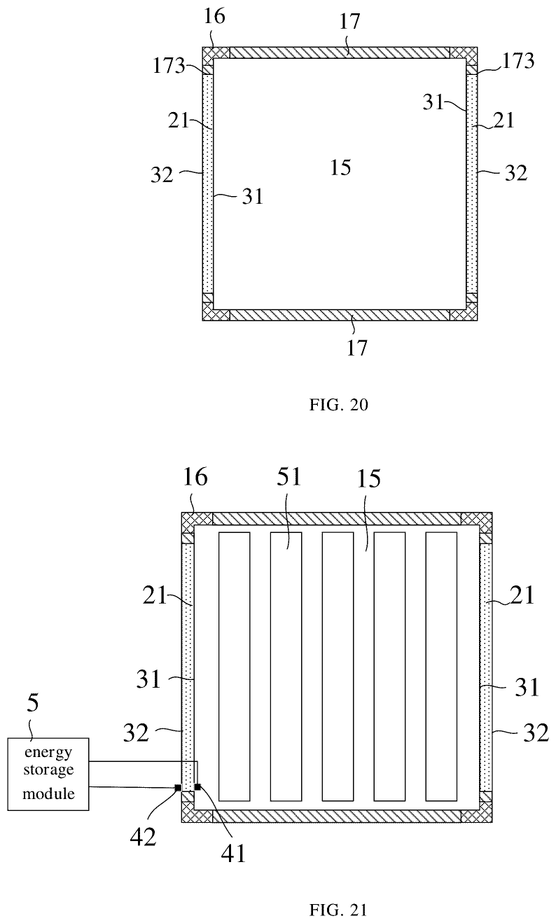

In some embodiments, as shown in FIG. 20, an embedding hole 173 is provided at the case plate 17, and the power generator 21 is embedded in the embedding hole 131. An inner diameter of the embedding hole 173 is matched with an outer diameter of the power generator 21, that is, the inner diameter of the embedding hole 173 is consistent with the outer diameter of the power generator 21 within a tolerance range, so that the power generator 21 may be embedded in the embedding hole 173.

In the embodiments of the present application, since the power generator 21 is connected to the case plate 17 in an embedded manner, the case plate 17 does not block the first end face 31 and the second end face 32 of the power generator 21, and the first end face 31 and the second end face 32 of the power generator 21 may be fully exposed to the accommodating space 15 and the environment outside the case 1, respectively. Therefore, the temperature difference between the first end face 31 and the second end face 32 of the power generator 21 is increased, so that the power generation efficiency of the power generator 21 is improved, thereby improving the recovery efficiency of the waste heat.

In some embodiments, the power generator 21 is an integral structure. It should be noted that the power generator 21 being the integral structure is relative to the side surface of the case frame 16, that is, one side surface of the case frame 16 is provided with one power generator 21. In a case where the power generator 21 is directly fixed to the case frame 16, the size of the power generator 21 may be set according to a requirement of the size of the case frame 16 to enable the power generator 21 to occupy the entire side surface of the case frame 16. In a case where the power generator 21 is attached to the case plate 17 or embedded in the embedding hole 173, the size of the power generator 21 is slightly smaller than that of the case plate 17, that is, instead of being directly fixed to the case frame 16, the power generator 21 is disposed on the case frame 16 through the case plate 17, and each case plate 17 is provided with one power generator 21.

According to the embodiments of the present application, the integral structure of the power generator 21 can reduce installation difficulty of the power generator 21 and the case and improve installation efficiency.

In some embodiments, the power generator 21 includes a plurality of sub-power generators 33, which are arranged on the case frame 16 at intervals or side by side, and are connected in parallel or in series through conductors.

The plurality of sub-power generators 33 being arranged at intervals refers to that a gap is provided between every two adjacent sub-power generators 33, and a width of the gap may be set as required. The plurality of sub-power generators 33 being arranged side by side refers to that no gap is provided between every two adjacent sub-power generators 33, or a gap is needed simply for assembly and a gap with a certain width is not designed.

As shown in FIG. 14, the power generator 21 includes two sub-power generators 33 arranged side by side.

In a case where the plurality of sub-power generators 33 are directly fixed to the case frame 16, the plurality of sub-power generators 33 are arranged side by side on the case frame 16, and the gap between every two adjacent sub-power generators 33 is reduced as much as possible, so as to prevent the heat from being discharged from the accommodating space 15 through the gap between every two adjacent sub-power generators 33 and avoid a reduction in the recovery efficiency of the waste heat such caused.

In a case where the plurality of sub-power generators 33 are fixed to the blind hole 171 of the case plate 17, the plurality of sub-power generators 33 may be arranged at intervals or side by side. For example, a plurality of blind holes 171 are provided at intervals on the case plate 17, and the plurality of sub-power generators 33 are disposed in the plurality of blind holes 171 in a one-to-one correspondence manner, or one blind hole 171 is provided on the case plate 17, and the plurality of sub-power generators 33 are disposed side by side in the blind hole 171.

In a case where the plurality of sub-power generators 33 are fixed in the embedding hole 173 of the case plate 17, the plurality of sub-power generators 33 are arranged side by side on the case frame 16, and the gap between every two adjacent sub-power generators 33 is reduced as much as possible, so as to prevent the heat from being discharged from the accommodating space 15 through the gap between every two adjacent sub-power generators 33 and avoid a reduction in the recovery efficiency of the waste heat such caused.

In a case where the plurality of sub-power generators 33 are fixed in the embedding holes 173 of the case plate 17, the number of embedding holes 173 is the same as that of the sub-power generators 33, and each sub-power generator 33 is embedded in one embedding hole 173 correspondingly. During assembly, the sub-power generators 33 can be quickly fixed to the case plate 17 with the embedding holes 173, thereby improving the assembly efficiency.

It should be noted that the power generator 21 may be disposed on each side surface of the case 1 in the same way or in different ways. Illustratively, the power generator 21 is directly fixed to the case frame 16 on each side surface of the case 1. Illustratively, the power generators 21 are directly fixed to the case frame 16 on the left side surface and the right side surface of the case 1, while the power generators 21 are fixed to the case plates 17 on the top side surface and the front side surface of the case 1. The case 1 may be an integral structure or other suitable structures, which is not limited herein.

In the super computing device provided in the embodiments of the present application, the integral structure of the case 1 can simplify an assembly process and improve the assembly efficiency of the super computing device, thereby reducing production cost of the super computing device.

In the embodiments of the present application, when the plurality of sub-power generators 33 are electrically connected in parallel, a current value output by the power generator 21 can be increased. When the plurality of sub-power generators 33 are electrically connected in series, a voltage value output by the power generator can be increased.

The power generator 21 includes three sub-power generators 33 each including a first end face 31 and a second end face 32 opposite to each other, a first lead terminal 41 is disposed on the first end face 31, and a second lead terminal 42 is disposed on the second end face 32. In a case where there is a temperature difference between the first end face 31 and the second end face 32 of the sub-power generator 33, electric energy may be generated in the sub-power generator 33, and may be output through lead wires connected to the first lead terminal 41 and the second lead terminal 42.

According the embodiments of the present application, the power generator is arranged in the form of the plurality of sub-power generators, and the plurality of sub-power generators are arranged on the case at intervals or side by side, so that the sub-power generators can be arranged flexibly according to a size of the case, the space of the case can be effectively utilized, and the heat recovery efficiency of the power generator can be improved.

FIG. 6 is the schematic diagram illustrating the parallel connection of part of the sub-power generators of the power generator. As shown in FIG. 6, the power generator 21 includes the three sub-power generators 33a, 33b, 33c, the first lead terminal 41 of the sub-power generator 33a, the first lead terminal 41 of the sub-power generator 33b, and the first lead terminal 41 of the sub-power generator 33c are electrically connected, and the second lead terminal 42 of the sub-power generator 33a, the second lead terminal 42 of the sub-power generator 33b, and the second lead terminal 42 of the sub-power generator 33c are electrically connected, thereby connecting the three sub-power generators 33a, 33b, 33c in parallel and outputting the electric energy generated by the three sub-power generators 33a, 33b, 33c.

FIG. 7 is the schematic diagram illustrating the series connection of part of the sub-power generators of the power generator. As shown in FIG. 7, the power generator 21 includes the three sub-power generators 33a, 33b, 33c, the second lead terminal 42 of the sub-power generator 33a is electrically connected to the first lead terminal 41 of the sub-power generator 33b, and the second lead terminal 42 of the sub-power generator 33b is electrically connected to the first lead terminal 41 of the sub-power generator 33c, thereby outputting the electric energy generated by the three sub-power generators 33a, 33b, 33c through the first lead terminal 41 of the sub-power generator 33a and the second lead terminal 42 of the sub-power generator 33c.

It should be noted that the case where the power generator 21 includes only three sub-power generators 33 as illustrated by FIG. 6 and FIG. 7 is not intended to limit the number of the sub-power generators 33, and the number of the sub-power generators 33 is not limited in the embodiments of the present application.

In some embodiments, a material of the power generator 21 is a semiconductor material. Illustratively, the semiconductor material includes bismuth telluride or other semiconductor materials.

In the super computing device provided in the embodiments of the present application, with bismuth telluride used as the power generation material, the power generation efficiency and the operation stability of the super computing device can be improved due to good electrical conductivity of bismuth telluride.

In some embodiments, a material of the lead terminals 4 is a conductive metal such as copper. Copper has good electrical conductivity and is low in cost. In some embodiments, Teflon lead wires or other high temperature-resistant lead wires may be used as the lead wires connected to the lead terminals 4.

In some embodiments, plating layers (not shown) are disposed on surfaces of the power generator 21 and the lead terminals 4. In a case where the material of the power generator 21 is not favorable for welding, for example, it is not easy for coating a solder, the plating layer can improve weldability of the power generator 21.

In some embodiments, a material of the plating layers is nickel or tin. In a case where the material of the power generator 21 is bismuth telluride and the solder is a tin-bismuth alloy, bismuth telluride may be melted into the solder, and copper impurities may easily diffuse into bismuth telluride at a relatively low temperature, which worsens thermoelectric property of bismuth telluride. The plating layers made of nickel or tin may serve as barriers to prevent the copper impurities from diffusing into bismuth telluride, thereby avoiding deterioration of the thermoelectric property of bismuth telluride. Disposing the plating layers made of nickel or tin on the surfaces of the lead terminals 4 can also facilitate the improvement in welding performance of the lead terminals 4. In some embodiments, a thickness of the plating layers is in a range of 0.1 mm to 0.3 mm.

In the super computing device provided in the embodiments of the present application, electrical connection performance of the power generator and the lead terminals can be improved due to good electrical conductivity of nickel or tin.

In some embodiments, as shown in FIG. 9, the package layer 33 is disposed on an outer surface of the power generator 21 and covers the power generator 21. One end of the lead terminal 4 is disposed at the power generator 21, and the other end of the lead terminal 4 is disposed on an outer side of the package layer 33, that is, the other end of the lead terminal 4 is exposed from the package layer 33 for facilitating electrical connection.

In some embodiments, a material of the package layer 33 is ceramic or other suitable materials. Using ceramic as the material of the package layer 33 has the advantages of low material cost, mature process, and excellent performance.

In some embodiments, the first end face 31 of the power generator 21 is a hot end face, the second end face 32 of the power generator 21 is a cold end face, the first end face 31 is disposed facing the accommodating space 15, and the second end face 32 is disposed away from the accommodating space 15.

The computing board 11 is disposed in the accommodating space 15, and discharges a large amount of heat during operation, such that the temperature of the accommodating space 15 is relatively high, and a temperature of the inner side of the case 1 is higher than a temperature of the outer side of the case 1. Disposing the hot end face of the power generator 21 facing the inner side of the case 1 and the cold end face of the power generator 21 facing the outer side of the case 1 can facilitate the improvement in the power generation efficiency of the power generator 21.

In the super computing device provided in the embodiments of the present application, by disposing the hot end face of the power generator 21 facing the accommodating space and the cold end face of the power generator 21 away from accommodating space, the power generation efficiency of the power generator 21 can be improved.

In some embodiments, the lead terminals 4 disposed on the first end face 31 and the second end face 32 are electrically connected to a power-consuming component in the super computing device to provide electrical signals to the power-consuming component. The power-consuming component may the computing board or other components such as a fan and a controller.

In the super computing device provided in the embodiments of the present application, the lead terminals are electrically connected to the power-consuming component in the super computing device, so that the power-consuming component in the super computing device can directly use the electric energy generated by the power generator, which can improve the energy efficiency ratio of the super computing device.

By electrically connecting the lead terminals 4 of the power generator 21 to the component in the super computing device and directly supplying the electric energy generated by the power generator 21 to the super computing device, the energy efficiency ratio of the super computing device is improved.

In some embodiments, as shown in FIG. 11, in addition to including the case 1, the computing board 11, and the power generator 21, the super computing device further includes an energy storage module 5, and two input terminals of the energy storage module 5 are electrically connected to the first lead terminal 41 disposed on the first end face 31 and the second lead terminal 42 disposed on the second end face 32 respectively for storing the electric energy output from the power generator 21.

The energy storage module 5 may be a storage battery or other modules capable of storing electric energy, and the form of the energy storage module 5 is not limited in the present application. The energy storage module 5 may be further connected to other power-consuming devices for supplying electric energy to the other power-consuming devices. The other power-consuming devices may be power-consuming devices in the super computing device or power-consuming devices outside the super computing device.

In some embodiments, the super computing device further includes a voltage stabilizer 47, two input terminals of the voltage stabilizer 47 are electrically connected to the lead terminals disposed on the first end face 31 and the second end face 32 respectively, and two output terminals of the voltage stabilizer 47 are electrically connected to the two input terminals of the energy storage module 5 correspondingly, that is, the voltage stabilizer 47 is disposed between output terminals of the power generator 21 and the energy storage module 5, and the electric energy is stored in the energy storage module 5 through the voltage stabilizer 47.

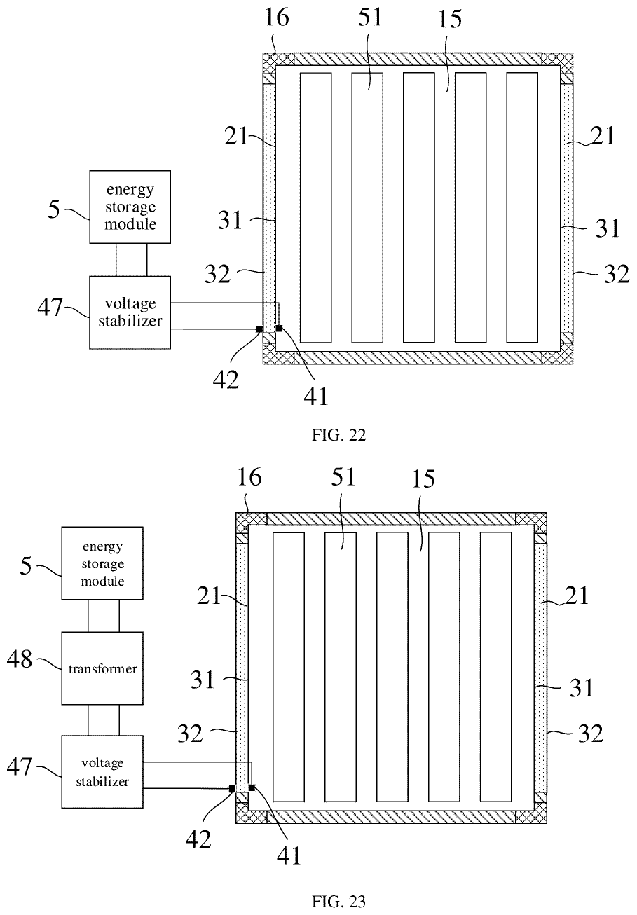

As shown in FIG. 22, the first end face 31 of the power generator 21 is electrically connected to the first input terminal of the voltage stabilizer 47 through the first lead terminal 41, the second end face 32 of the power generator 21 is electrically connected to the second input terminal of the voltage stabilizer 47 through the second lead terminal 42, the first output terminal of the voltage stabilizer 47 is electrically connected to the first input terminal of the energy storage module 5, and the second output terminal of the voltage stabilizer 47 is electrically connected to the second input terminal of the energy storage module 5.

In the super computing device provided in the embodiments of the present application, the voltage stabilizer can improve stability of quantity of the electric energy input to the energy storage module and prolong service life of the energy storage module.

In some embodiments, the super computing device further includes a transformer 48, the two input terminals of the voltage stabilizer 47 are electrically connected to the lead terminals disposed on the first end face 31 and the second end face 32 respectively, the two output terminals of the voltage stabilizer 47 are electrically connected to two input terminals of the transformer 48 respectively, and two output terminals of the transformer 48 are electrically connected to the two input terminals of the energy storage module 5 respectively, that is, the voltage stabilizer 47 and the transformer 48 are sequentially disposed between the output terminals of the power generator 21 and the energy storage module 5, and the electric energy is stored in the energy storage module 5 through the voltage stabilizer 47 and the transformer 48.

As shown in FIG. 23, the first end face 31 of the power generator 21 is electrically connected to the first input terminal of the voltage stabilizer 47 through the first lead terminal 41, the second end face 32 of the power generator 21 is electrically connected to the second input terminal of the voltage stabilizer 47 through the second lead terminal 42, the first output terminal of the voltage stabilizer 47 is electrically connected to the first input terminal of the transformer 48, and the second output terminal of the voltage stabilizer 47 is electrically connected to the second input terminal of the transformer 48. The first output terminal of the transformer 48 is electrically connected to the first input terminal of the energy storage module 5, and the second output terminal of the transformer 48 is electrically connected to the second input terminal of the energy storage module 5.

In the super computing device provided in the embodiments of the present application, the transformer disposed between the voltage stabilizer and the energy storage module can improve charge efficiency, so that the electric energy generated by the power generator can be stored on time.

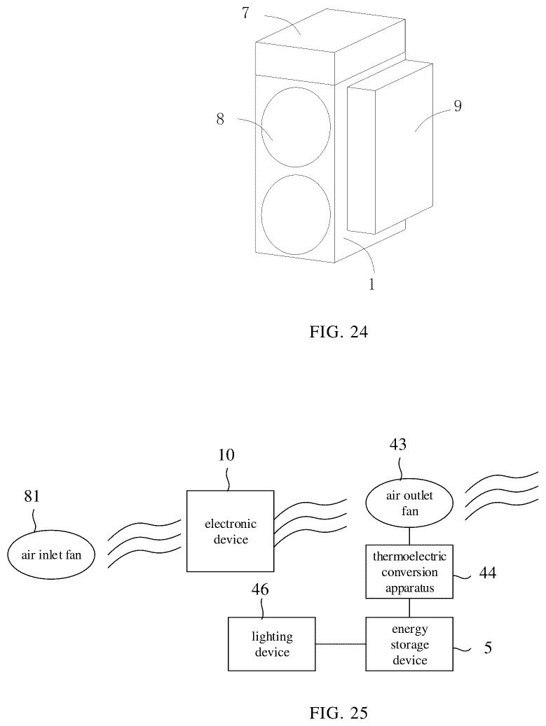

In some embodiments, as shown in FIG. 14 and FIG. 24, the super computing device further includes one or more of a heat sink 6, a control board 7, a fan 8, and a power supply 9.

The heat sink 6 is attached to the computing board 11, and is configured to discharge the heat generated by the computing board. The heat sink 6 may be made of a material having high thermal conductivity, such as aluminum. The heat sink 6 includes a heat dissipation body and a plurality of fins, the plurality of fins are arranged at intervals on a surface of the heat dissipation body, the heat dissipation body is attached to the computing board 11, and a heat conduction glue is disposed between the heat dissipation body and the computing board 11 for improving heat dissipation efficiency of the heat sink 6.

The control board 7 is disposed on the outer side of the case 1, and is configured to control the computing board 11. The control board 7 is connected to the computing board 11 through a cable, and performs information interaction with the computing board 11 through the cable. The control board 7 may be disposed on the top side surface of the case 1, or may be disposed on the left side surface or the right-side surface of the case 1 according to actual situations.

In some embodiments, the control board 7 is connected to the fan 8 through a signal line for controlling the fan 8 to be turned on or off and controlling output power of the fan 8. When a temperature in the case 1 is high, the control board 7 may increase the power of the fan 8, so as to increase the heat dissipation efficiency. The control board 7 may be further connected to the power supply 9 through a cable, so as to obtain the electric energy required by the operation of the control board 7 and control the power supply 9.

The fan 8 is disposed on the outer side of the case, and is configured to discharge the heat from the accommodating space. The fan 8 is configured to drive the air in the accommodating space 15 to flow, so as to accelerate the discharge of the heat from the accommodating space 15. When the temperature of the accommodating space 15 exceeds a preset first temperature threshold, the fan 8 may be turned on to lower the temperature in the accommodating space 15. When the temperature of the accommodating space 15 exceeds a preset second temperature threshold (which is greater than the first temperature threshold), the output power of the fan 8 may be increased to accelerate the lowering of the temperature in the accommodating space 15.

In some embodiments, the fan 8 is disposed on a side surface of the case 1, for example, the fan 8 is disposed on the rear side surface of the case 1, or the fan 8 is disposed on another side surface of the case 1 according to design needs.

It should be noted that the arrangement position of the fan 8 relative to the case 1 is not limited to the above description, and the fan 8 may be arranged in other suitable manners.

In some embodiments, the fan 8 includes a rotating shaft, blades, and a driving device, the blades are fixed at one end of the rotating shaft, an output terminal of the driving device is connected to the other end of the rotating shaft, the rotating shaft transmits a driving force from the driving device to the blades, and the blades are rotated to provide power for the flowing of the air in the accommodating space 15. The number of the blades may be 2, 3 or more, and is not limited in the present application. A plurality of blades are uniformly distributed along a circumferential direction of the rotating shaft, so as to provide the air in the accommodating space 15 with uniform power.

The power supply 9 is disposed on the outer side of the case, and is configured to supply the electric energy to the super computing device for operation, so as to ensure normal operation of all electronic components in the super computing device. The electronic components may further include a memory and a hard disk, and the hard disk is used for storage and installation of application programs. It should be noted that the power and a type of the power supply are not limited in the embodiments of the present application.

In the super computing device provided in the embodiments of the present application, the heat dissipation efficiency of the super computing device can be increased with the heat sink and the fan, so that the temperature of the accommodating space can be prevented from being too high and affecting the performance of the super computing device.

In some embodiments, the super computing device further includes a network interface card, which is provided with standard network ports and is configured to enable information interaction between the super computing device and other network devices.

In the super computing device provided in the embodiments of the present application, the computing board is disposed in the accommodating space of the case, the power generator is disposed on the case, and the computing board generates the heat during operation, thereby causing the first end face and the opposite second end face of the power generator to generate the electric energy. The electric energy is output through the lead terminals disposed on the first end face and the second end, and is recycled. In this way, the energy efficiency ratio of the super computing device is improved, and energy consumption and pollution are reduced.

An embodiment of the present application further provides a server, including at least one super computing device which adopts the super computing device provided in the embodiments of the present application. By recycling the heat discharged by the computing board during operation with the power generator disposed in the case, the energy efficiency ratio of the super computing device is improved while reducing energy consumption and pollution.

FIG. 25 is schematic diagram of an application scenario where a thermoelectric conversion apparatus is applied to an electronic device according to an embodiment of the present application. As shown in FIG. 25, an air inlet fan 81 provides a cooling medium for an electronic device 10, and the cooling medium may absorb and carry waste heat released by the electronic device 10. An air outlet fan 43 is configured to gather the cooling medium which absorbs the waste heat, and a thermoelectric conversion apparatus 44 generates electric energy by using the waste heat in the cooling medium. The cooling medium enters the atmosphere after the waste heat is recovered. An energy storage device 5 is configured to store the electric energy generated by the thermoelectric conversion apparatus 44, and a lighting device 46 is connected to the energy storage device 5, and can utilize the electric energy stored by the energy storage device 5. The electric energy stored in the energy storage device 5 may be also used to drive the air inlet fan 81 and/or the air outlet fan 43 to operate.

In some embodiments, the electronic device may be replaced with an electronic device group, that is, the single electronic device is replaced with the electronic device group composed of a plurality of electronic devices.

An embodiment of the present application further provides a waste heat recycling system, including: an electronic component, a thermoelectric conversion apparatus, and a power-consuming device. The electronic component is configured to perform a corresponding function, and the thermoelectric conversion apparatus is configured to convert waste heat generated when the electronic component performs the corresponding function into electric energy. Lead terminals of the thermoelectric conversion apparatus are electrically connected to the power-consuming device, and the thermoelectric conversion apparatus provides electrical signals to the power-consuming device through the lead terminals.

In some embodiments, the electronic component and the power-consuming device are two independent devices. For example, the electronic component is a component in a super computing device, such as a computing board, a control board, a network interface card, or a power supply, and the power-consuming device is a device outside the super computing device. The thermoelectric conversion apparatus recovers the waste heat generated by the super computing device, converts the waste heat into the electric energy, and supplies the electric energy to the power-consuming device outside the super computing device.

It should be understood by those of ordinary skill in the art that the functional modules/units in all or some of the steps, systems and devices disclosed above may be implemented as software, firmware, hardware, or suitable combinations thereof. If implemented as hardware, the division between the functional modules/units stated above is not necessarily corresponding to the division of physical components; and for example, one physical component may have a plurality of functions, or one function or step may be performed through cooperation of several physical components.

The present application discloses the exemplary embodiments using specific terms, but the terms are merely used and should be merely interpreted as having general illustrative meanings, rather than for the purpose of limitation. Unless expressly stated, it is apparent to those of ordinary skill in the art that features, characteristics and/or elements described in connection with a particular embodiment can be used alone or in combination with features, characteristics and/or elements described in connection with other embodiments. Therefore, it should be understood by those of ordinary skill in the art that various changes in the forms and the details can be made without departing from the scope of the present application of the appended claims.

What is claimed is:

1. A thermoelectric conversion apparatus, comprising:
a power generator comprising a first end face and a second end face opposite to each other;
lead terminals, both the first end face and the second end face of the power generator being provided with the lead terminals;
in a case where there is a temperature difference between the first end face and the second end face of the power generator, the power generator outputs electric energy through the lead terminals disposed on the first end face and the second end face of the power generator; and
a supporter configured to support and fix the power generator.

2. The thermoelectric conversion apparatus of claim 1, wherein the power generator is a hollow columnar structure.

3. The thermoelectric conversion apparatus of claim 2, wherein the supporter comprises a first hollow columnar structure, and the power generator is located on a surface of the first hollow columnar structure.

4. The thermoelectric conversion apparatus of claim 2, wherein the supporter comprises a first hollow columnar structure and a second hollow columnar structure, which are coaxially arranged and have different radii, and the power generator is located between the first hollow columnar structure and the second hollow columnar structure.

5. The thermoelectric conversion apparatus of claim 2, wherein the supporter is provided with a plurality of through holes penetrating through the supporter along a wall thickness direction of the supporter.

6. The thermoelectric conversion apparatus of claim 2, wherein the supporter is a case, and an accommodating space is formed in the case; and
the power generator is disposed on a surface of the case.

7. The thermoelectric conversion apparatus of claim 6, wherein the case comprises a plurality of side surfaces, and at least one of the plurality of side surfaces of the case is provided with the power generator.

8. The thermoelectric conversion apparatus of claim 7, wherein the power generator is attached to an inner side surface or an outer side surface of the case.

9. The thermoelectric conversion apparatus of claim 6, wherein the first end face of the power generator is a hot end face, the second end face of the power generator is a cold end face, the first end face of the power generator is disposed facing the accommodating space, and the second end face of the power generator is disposed away from the accommodating space.

10. The thermoelectric conversion apparatus of claim 1, wherein the lead terminals disposed on the first end face and the second end face are electrically connected to a power-consuming device for providing electrical signals to the power-consuming device.

11. The thermoelectric conversion apparatus of claim 1, wherein the power generator comprises a plurality of sub-power generators arranged at intervals along a circumferential direction of the supporter, and connected in parallel or in series through conductors.

12. The thermoelectric conversion apparatus of claim 1, wherein a material of the power generator is a semiconductor material comprising bismuth telluride; and
a material of the lead terminals is a conductive metal.

13. The thermoelectric conversion apparatus of claim 1, further comprising an energy storage module, wherein two input terminals of the energy storage module are electrically connected to the lead terminals disposed on the second end face and the first end face respectively, and the energy storage module is configured to store the electric energy output from the power generator.

14. The thermoelectric conversion apparatus of claim 13, further comprising a voltage stabilizer, wherein two input terminals of the voltage stabilizer are electrically connected to the lead terminals disposed on the first end face and the second end face respectively, and two output terminals of the voltage stabilizer are electrically connected to the two input terminals of the energy storage module correspondingly.

15. The thermoelectric conversion apparatus of claim 14, further comprising a transformer, wherein the two input terminals of the voltage stabilizer are electrically connected to the lead terminals disposed on the first end face and the second end face respectively, the two output terminals of the voltage stabilizer are electrically connected to two input terminals of the transformer respectively, and two output terminals of the transformer are electrically connected to the two input terminals of the energy storage module correspondingly.

16. The thermoelectric conversion apparatus of claim 1, further comprising a medium driving module, wherein the medium driving module comprises a rotating shaft, blades, and a driving device, the rotating shaft is arranged along a direction of a central axis of the supporter, the blades are fixed at one end of the rotating shaft, an output terminal of the driving device is connected to the other end of the rotating shaft, the rotating shaft transmits a driving force from the driving device to the blades, and the blades are configured to provide power for flowing of a heat transfer medium.

17. An electronic device, comprising an electronic component and a thermoelectric conversion apparatus configured to recycle heat generated by the electronic component, wherein the thermoelectric conversion apparatus comprises the thermoelectric conversion apparatus of claim 1.

18. The electronic device of claim 17, wherein the lead terminals of the thermoelectric conversion apparatus are configured to provide electrical signals to a component in the electronic component.

19. The electronic device of claim 17, wherein the electronic component is a super computing device.

20. A waste heat recycling system, comprising: an electronic component, a thermoelectric conversion apparatus, and a power-consuming device, wherein lead terminals of the thermoelectric conversion apparatus are electrically connected to the power-consuming device for providing electrical signals to the power-consuming device, wherein the thermoelectric conversion apparatus comprises the thermoelectric conversion apparatus of claim 1.
